(19) United States
(12) Patent Application Publication
(10) Pub. No.: US 2018/0020526 A1
(43) Pub. Date: Jan. 18, 2018

(54) ORGANIC ELECTROLUMINESCENCE DEVICE

(71) Applicant: SAMSUNG DISPLAY CO., LTD., Yongin-si (KR)

(72) Inventors: Junta FUCHIWAKI, Yokohama (JP); Tohru SATO, Kyoto-si (JP)

(21) Appl. No.: 15/481,695

(22) Filed: Apr. 7, 2017

(30) Foreign Application Priority Data
Jul. 12, 2016 (KR) 10-2016-0087833

(51) Int. Cl. H05B 33/14; H01L 51/52; C09K 11/06; H01L 51/50

(52) U.S. Cl. CPC H05B 33/145; H01L 51/5072; H01L 51/52; C09K 11/06; H01L 51/5056; H01L 51/5016; H01L 2251/30

(57) ABSTRACT

An organic electroluminescence device includes an anode, a hole transport region, an emission region, an electron transport region, and a cathode. The hole transport region is provided on the anode. The emission layer is provided on the hole transport region. The electron transport region is provided on the emission layer. The cathode is provided on the electron transport region. The emission layer includes a first compound represented by the following Formula 1 and a second compound represented by the following Formula 2.

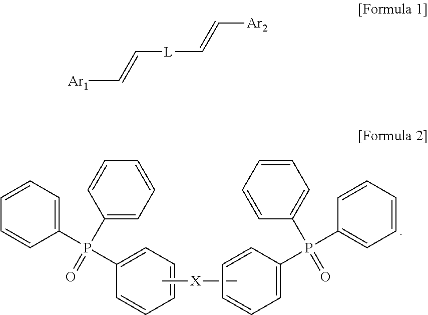

### CROSS-REFERENCE TO RELATED APPLICATION

Korean Patent Application No. 10-2016-0087833, filed on Jul. 12, 2016, in the Korean Intellectual Property Office, and entitled: “Organic Electroluminescence Device,” is incorporated by reference herein in its entirety.

### BACKGROUND

### 1. Field

Embodiments relate to an organic electroluminescence device.

### 2. Description of the Related Art

Recently, as an image display apparatus, developments on an organic electroluminescence display are being actively conducted. The organic electroluminescence display is different from a liquid crystal display, and is a self-luminescent display attaining display by emitting a luminescent material including an organic compound in an emission layer via the recombination of holes and electrons respectively injected from an anode and a cathode in an emission layer.

### SUMMARY

Embodiments are directed to an organic electroluminescence device including an anode, a hole transport region, an emission layer, an electron transport region, and a cathode. The hole transport region is provided on the anode. The emission layer is provided on the hole transport region. The electron transport region is provided on the emission layer. The cathode is provided on the electron transport region. The emission layer includes a first compound represented by the following Formula 1 and a second compound represented by the following Formula 2.

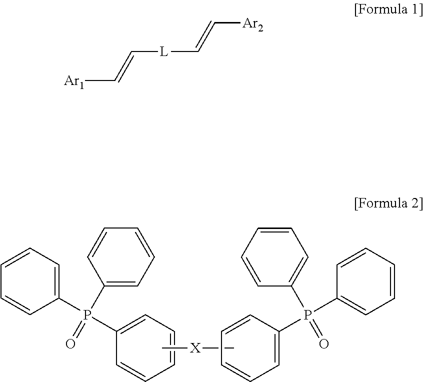

In Formulae 1 and 2, L is selected from a substituted or unsubstituted arylene having 6 to 30 carbon atoms for forming a ring, or a substituted or unsubstituted heteroarylene having 4 to 30 carbon atoms for forming a ring, X is a divalent linker, and Ar₁ and Ar₂ are each independently represented by the following Formula 3.

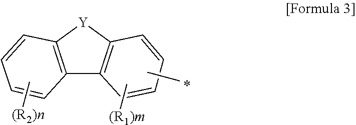

In Formula 3, Y is selected from O, S, NR₃, CR₄R₅, or SiR₆R₇, R₁ and R₂ are each independently selected from a substituted or unsubstituted alkyl having 1 to 20 carbon atoms, a substituted or unsubstituted aryl having 6 to 30 carbon atoms for forming a ring, a substituted or unsubstituted heteroaryl having 4 to 30 carbon atoms for forming a ring, a substituted or unsubstituted alkoxy, a substituted or unsubstituted aryloxy, a substituted or unsubstituted amino, a substituted or unsubstituted cyano, a substituted or unsubstituted silyl, halogen, deuterium, or hydrogen, R₃, R₄, R₅, R₆, and R₇ are each independently selected from a substituted or unsubstituted alkyl having 1 to 20 carbon atoms, a substituted or unsubstituted aryl having 6 to 30 carbon atoms for forming a ring, or a substituted or unsubstituted heteroaryl having 4 to 30 carbon atoms for forming a ring, m is an integer of 0 to 3, and n is an integer of 0 to 4.

In Formula 3, * represents a binding site.

In an embodiment, a triplet excitation energy of the second compound may be higher than a singlet excitation energy of the first compound.

In Formula 1, Ar₁ and Ar₂ in Formula 1 may be the same.

In Formula 1, Ar₁ and Ar₂ in Formula 1 may be each independently selected from a substituted or unsubstituted carbazole, a substituted or unsubstituted dibenzofuran, a substituted or unsubstituted dibenzothiophene, a substituted or unsubstituted fluorenyl, or a substituted or unsubstituted dibenzosilole.

In Formula 1, L may be selected from the following A-1 to A-6.

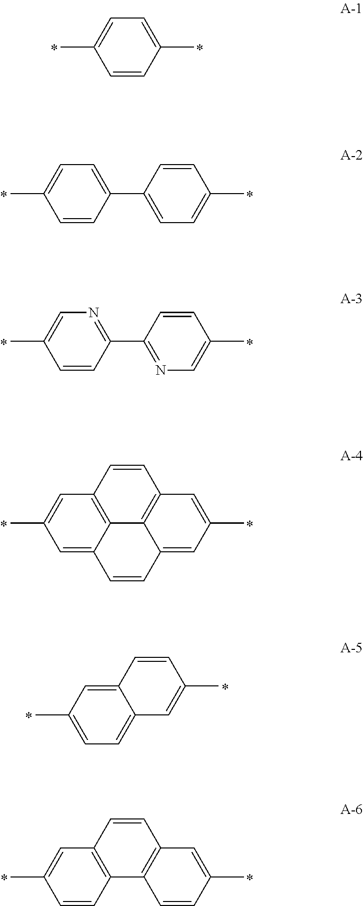

In A-1 to A-6, * represents a binding site.

In Formula 2, X may be O.

In Formula 3, in may be an integer of 1 to 3, n may be an integer of 1 to 4, and R₁ and R₂ may be each independently selected from the following B-1 to B-8:

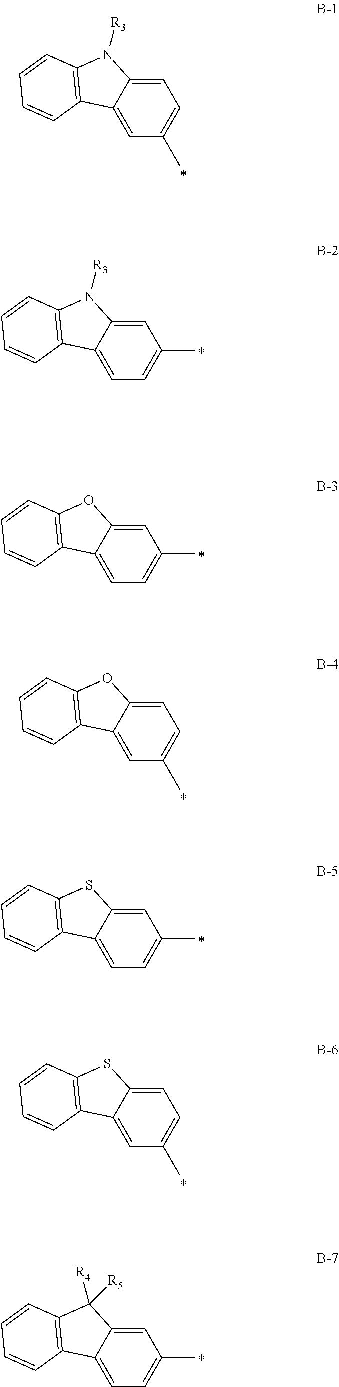

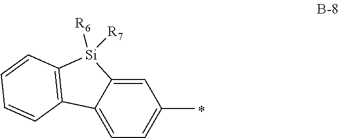

In B-1 to B-8, * represents a binding site.

In Formula 3, Y may be NR₃, and R₃ may be ethyl or phenyl.

In Formula 3, Y may be CR₄R₅, and R₄ and R₅ may be each independently methyl or phenyl.

In Formula 3, Y may be SiR₆R₇, and R₆ and R₇ may be each independently methyl or phenyl.

In an embodiment, the first compound may include at least one of the compounds represented in the following Compound Group 1.

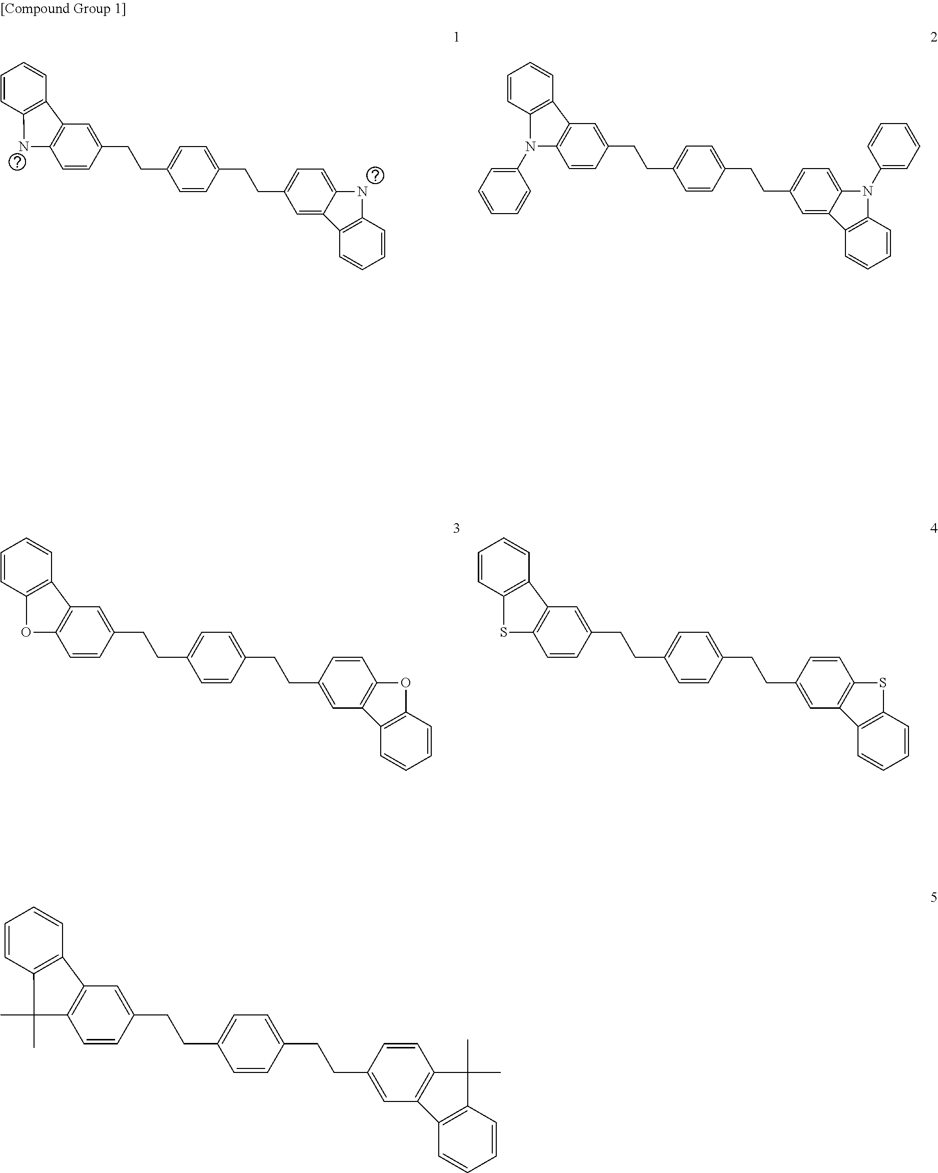

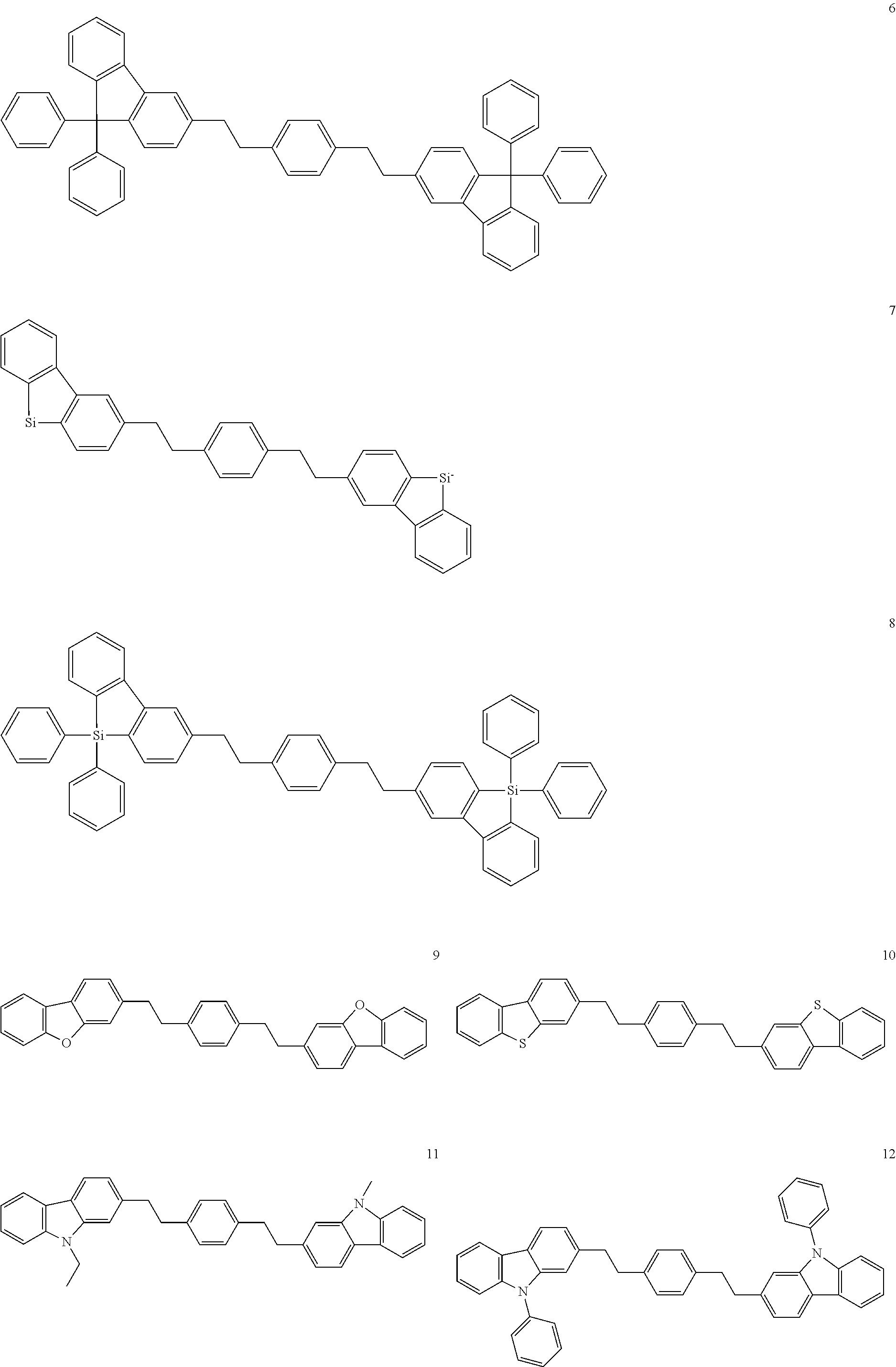

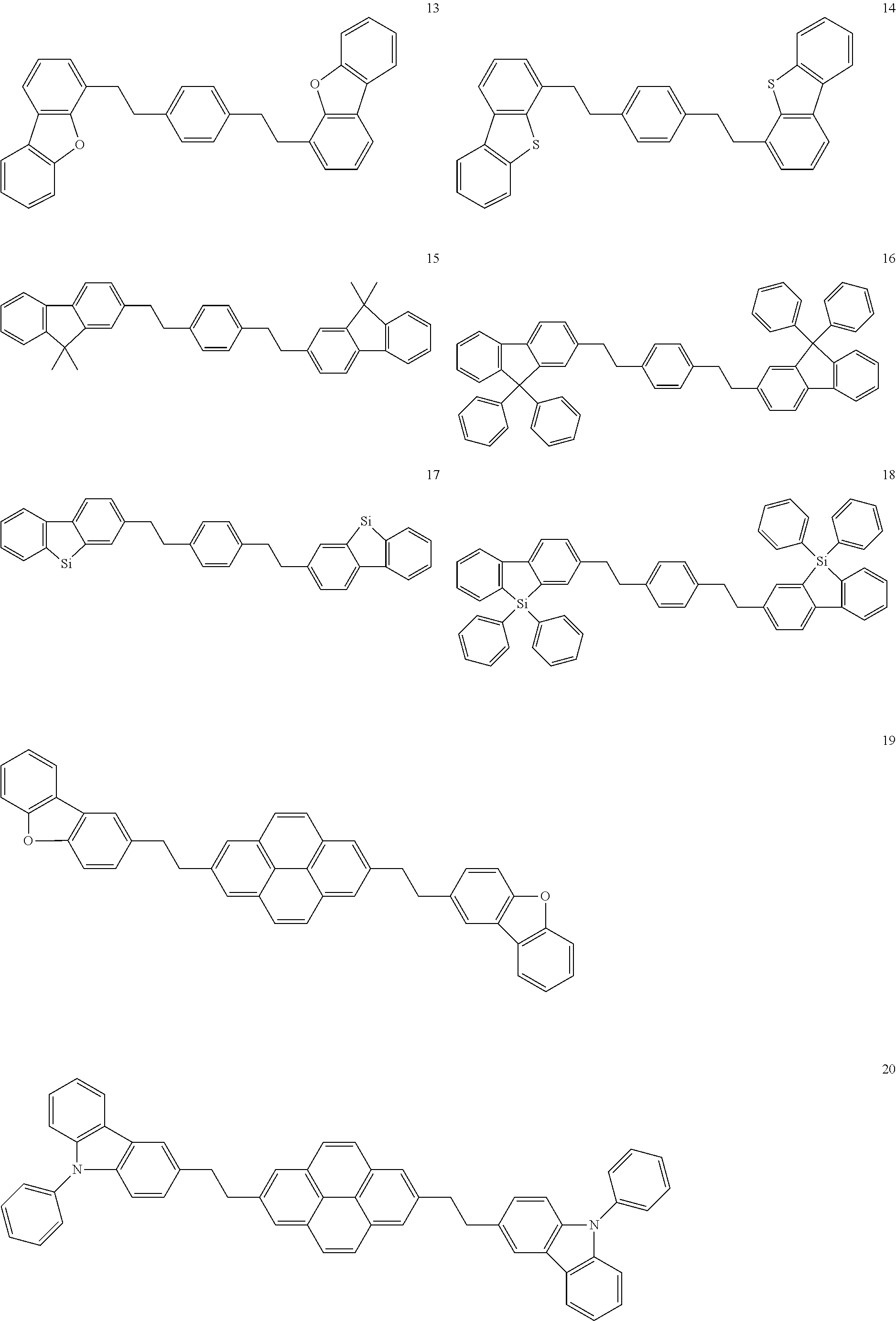

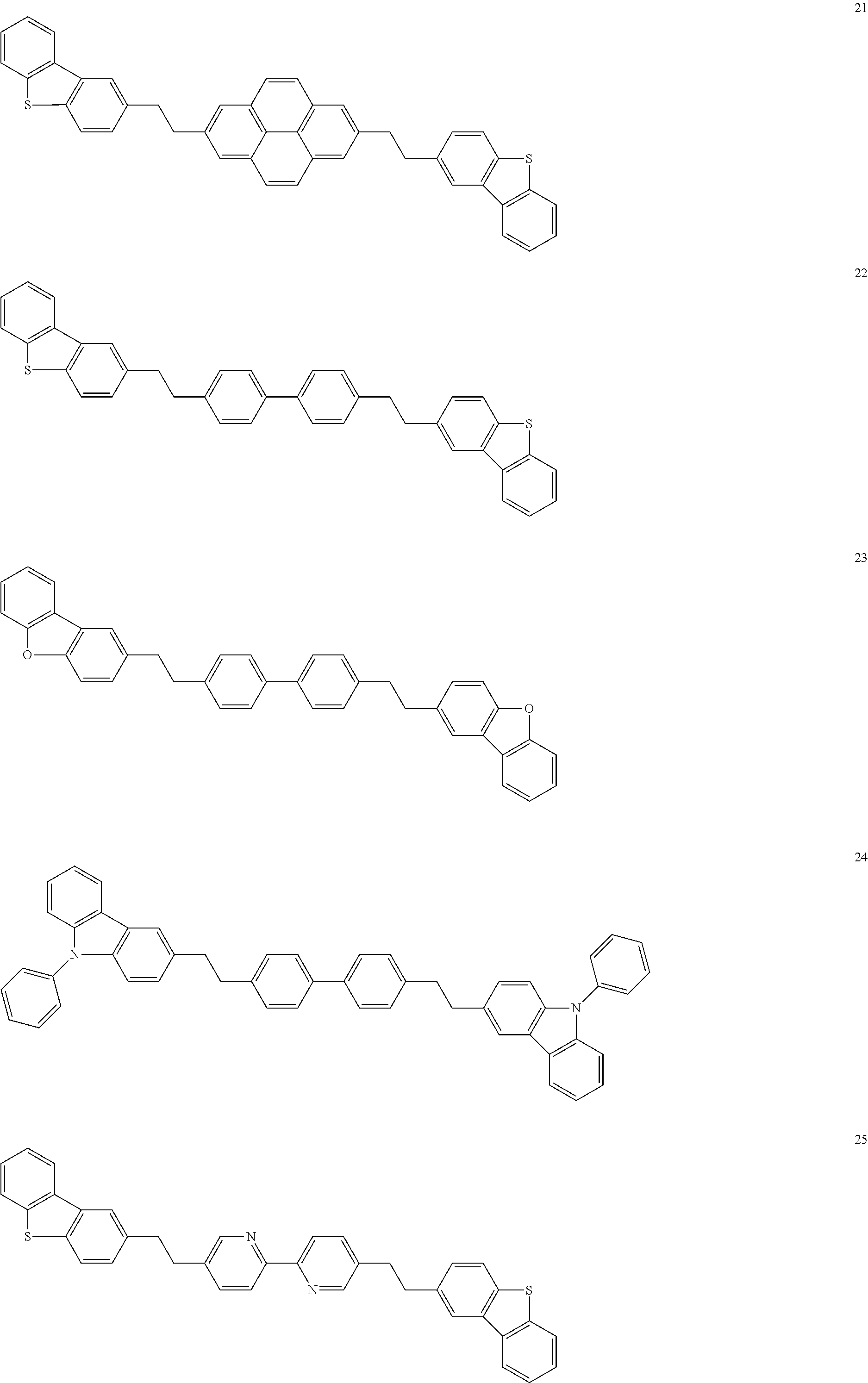 [SMILES: c1ccc2c(c1)sc1ccc(CCc3cc4ccc5cc(CCc6ccc7sc8ccccc8c7c6)cc6ccc(c3)c4c56)cc12 ; c1ccc2c(c1)sc1ccc(CCc3ccc(-c4ccc(CCc5ccc6sc7ccccc7c6c5)cc4)cc3)cc12 ; c1ccc2c(c1)oc1ccc(CCc3ccc(-c4ccc(CCc5ccc6oc7ccccc7c6c5)cc4)cc3)cc12 ; c1ccc(-n2c3ccccc3c3cc(CCc4ccc(-c5ccc(CCc6ccc7c(c6)c6ccccc6n7-c6ccccc6)cc5)cc4)ccc32)cc1 ; c1ccc2c(c1)sc1ccc(CCc3ccc(-c4ccc(CCc5ccc6sc7ccccc7c6c5)cn4)nc3)cc12]

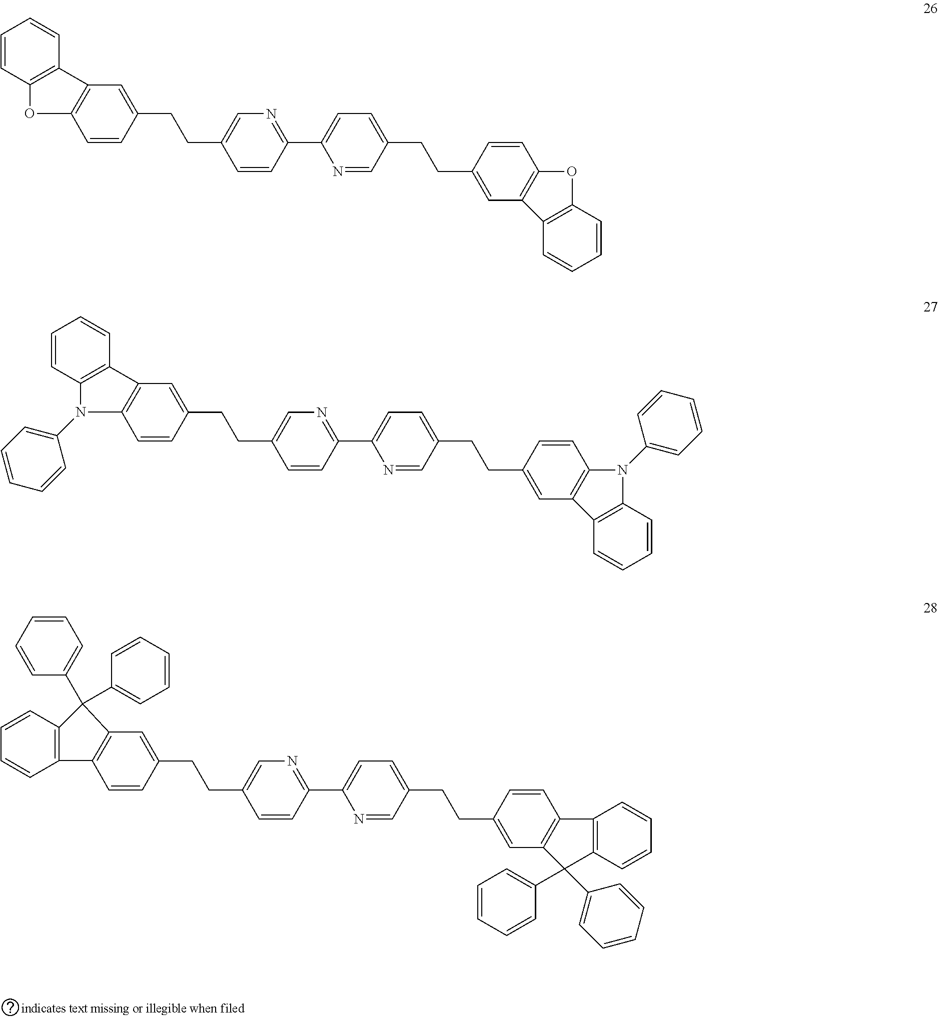 [SMILES: c1ccc2c(c1)oc1ccc(CCc3ccc(-c4ccc(CCc5ccc6oc7ccccc7c6c5)cn4)nc3)cc12 ; c1ccc(-n2c3ccccc3c3cc(CCc4ccc(-c5ccc(CCc6ccc7c(c6)c6ccccc6n7-c6ccccc6)cn5)nc4)ccc32)cc1 ; c1ccc(C2(c3ccccc3)c3ccccc3-c3ccc(CCc4ccc(-c5ccc(CCc6ccc7c(c6)C(c6ccccc6)(c6ccccc6)c6ccccc6-7)cn5)nc4)cc32)cc1]

In an embodiment, the second compound may be

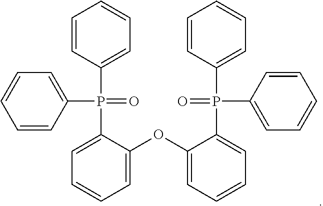 [SMILES: O=P(c1ccccc1)(c1ccccc1)c1ccccc1Oc1ccccc1P(=O)(c1ccccc1)c1ccccc1]

In an embodiment, the first compound may be a dopant, and the second compound may be a host. The host may be present in a greater weight percentage than the dopant in the emission layer.

In an embodiment, the hole transport region may include a hole injection layer, and a hole transport layer provided on the hole injection layer.

In an embodiment, the electron transport region may include an electron transport layer, and an electron injection layer provided on the electron transport layer.

### BRIEF DESCRIPTION OF THE DRAWINGS

Features will become apparent to those of skill in the art by describing in detail exemplary embodiments with reference to the attached drawings in which:

FIG. 1 illustrates a schematic diagram illustrating an organic electroluminescence device according to an embodiment; and

FIG. 2 illustrates a schematic diagram illustrating an organic electroluminescence device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art. In the drawing figures, the dimensions of layers and regions may be exaggerated for clarity of illustration. Like reference numerals refer to like elements throughout.

It will be understood that, although the terms first, second, etc. may be used herein to describe various elements, these elements should not be limited by these terms. These terms are only used to distinguish one element from another element. For example, a first element could be termed a second element, and similarly, a second element could be termed a first element. As used herein, the singular forms are intended to include the plural forms as well, unless the context clearly indicates otherwise.

It will be further understood that the terms “comprises” or “comprising,” when used in this specification, specify the presence of stated features, numerals, steps, operations, elements, parts, or a combination thereof, but do not preclude the presence or addition of one or more other features, numerals, steps, operations, elements, parts, or a combination thereof. It will also be understood that when a layer, a film, a region, a plate, etc. is referred to as being ‘on’ another part, it can be directly on the other part, or intervening layers may also be present. On the contrary, when a layer, a film, a region, a plate, etc. is referred to as being ‘under’ another part, it can be directly under the other part, or intervening layers may also be present.

In the present disclosure, “substituted or unsubstituted” may mean substituted with at least one substituent selected from the group consisting of deuterium, halogen, nitrile, nitro, amino, silyl, boron, phosphine oxide, alkyl, alkoxy, alkenyl, fluorenyl, aryl, and heteroaryl, or unsubstituted. In addition, each of the substituent illustrated above may be substituted or unsubstituted. For example, biphenyl may be interpreted as aryl, or phenyl substituted with phenyl.

In the present disclosure, the term “forming a ring via the combination of adjacent groups” may mean forming a substituted or unsubstituted cyclic hydrocarbon, or a substituted or unsubstituted heterocycle via the combination of adjacent groups. The cyclic hydrocarbon may include aliphatic cyclic hydrocarbon and aromatic cyclic hydrocarbon. The heterocycle may include aliphatic heterocycle and aromatic heterocycle. The cyclic hydrocarbon and heterocycle may be a monocycle or polycycle. In addition, the ring formed via the combination of adjacent groups may be connected with another ring to form a Spiro structure.

In the present disclosure, the term “adjacent groups” may mean a substituent substituted with an atom directly connected with another atom substituted with a corresponding substituent, a different substituent substituted with an atom substituted with a corresponding substituent, or a substituent disposed stereoscopically at the nearest position to a corresponding substituent. For example, two methyl groups in 1,2-dimethylbenzene may be interpreted as “adjacent groups”, and two ethyl groups in 1,1-diethylcyclopentene may be interpreted as “adjacent groups”.

In the present disclosure, halogen may include fluorine, chlorine, bromine, or iodine.

In the present disclosure, the alkyl may have a linear or branched chain or a cycle shape. The carbon number of the alkyl may be 1 to 30, 1 to 20, 1 to 10, or 1 to 6. Examples of the alkyl may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldodecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyl eicosyl, 2-butyl eicosyl, 2-hexyl eicosyl, 2-octyl eicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the present disclosure, the aryl means an optional functional group or substituent derived from aromatic cyclic hydrocarbon. The aryl may be monocyclic aryl or polycyclic aryl. The carbon number of the aryl for forming a ring may be 6 to 30, or 6 to 20. Examples of the aryl may include phenyl, naphthyl, fluorenyl, anthracenyl, phenanthryl, biphenyl, terphenyl, quaterphenyl, quinqphenyl, sexiphenyl, triphenylene, pyrenyl, benzofluoranthenyl, chrysenyl, etc., without limitation.

In the present disclosure, the fluorenyl may be substituted, or two substituents may be combined to form a spiro structure.

In the present disclosure, the heteroaryl may be heteroaryl including at least one of O, N, P, or S as a heteroatom. The carbon number of the heteroaryl for forming a ring may be 2 to 30, or 2 to 20. Examples of the heteroaryl may include thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phenoxazyl, phthalazinyl, pyrido pyrimidinyl, pyrido pyrazinyl, pyrazino pyrazinyl, isoquinoline, indole, carbazole, N-arylcarbazole, N-heteroaryl carbazole, N-alkyl carbazole, benzoxazole, benzoimidazole, benzothiazole, benzocarbazole, benzothiophene, dibenzothiophene, thienothiophene, benzofuranyl, phenanthroline, thiazolyl, isooxazolyl, oxadiazolyl, thiadiazolyl, benzothiazolyl, phenothiazinyl, dibenzofuranyl, etc., without limitation.

In the present disclosure, the explanation on the aryl may be applied to the arylene except for the case where the arylene is a divalent group.

In the present disclosure, the silyl may include alkylsilyl and arylsilyl. Examples of the silyl may include trimethylsilyl, triethylsilyl, t-butyl dimethylsilyl, vinyl dimethylsilyl, propyl dimethylsilyl, triphenylsilyl, diphenylsilyl, phenylsilyl, etc., without limitation.

In the present disclosure, the boron group may include alkyl boron and aryl boron. Examples of the boron group may include trimethyl boron, triethyl boron, t-butyl dimethyl boron, triphenyl boron, diphenyl boron, phenyl boron, etc., without limitation.

In the present disclosure, the alkenyl may be linear or branched. The carbon number is not specifically limited, however may be 2 to 30, 2 to 20, or 2 to 10. Examples of the alkenyl may include vinyl, 1-butenyl, 1-pentenyl. 1,3-butadienyl aryl, styrenyl, styrylvinyl, etc., without limitation.

Hereinafter an organic electroluminescence device according to an example embodiment will be explained.

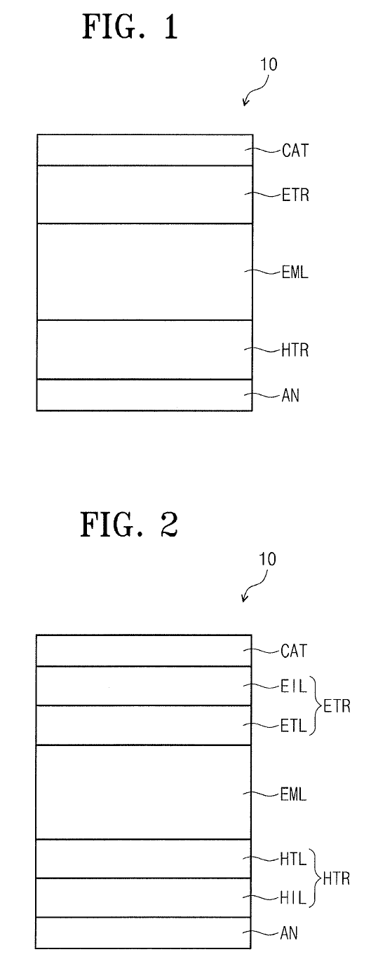

FIG. 1 is a cross-sectional view schematically illustrating an organic electroluminescence device according to an embodiment. FIG. 2 is a cross-sectional view schematically illustrating an organic electroluminescence device according to an embodiment.

Referring to FIGS. 1 and 2, an organic electroluminescence device 10 according to an example embodiment includes an anode AN, a hole transport region HTR, an emission layer EML, an electron transport region ETR, and a cathode CAT.

The anode AN has conductivity. The anode AN may be a pixel electrode or an anode. The anode AN may be a transmissive electrode, a transflective electrode, or a reflective electrode. In the case where the anode AN is the transmissive electrode, the anode AN may be formed using, for example, a transparent metal oxide such as indium tin oxide (ITO), indium zinc oxide (IZO), zinc oxide (ZnO), and indium tin zinc oxide (ITZO). In the case where the anode AN is the transflective electrode or the reflective electrode, the anode AN may include, for example, Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). Also, the anode AN may include a plurality of layers including a reflective layer or a transflective layer formed using the above materials, and a transmissive layer formed using ITO, IZO, ZnO, or ITZO.

The hole transport region HTR may be provided on the anode AN. The hole transport region HTR may include a hole transport layer HTL. The hole transport region HTR may further include at least one of a hole injection layer HIL, a hole buffer layer, or an electron blocking layer. The thickness of the hole transport region HTR may be, for example, from about 1,000 Å to about 1,500 Å. The thickness of the hole transport region HTR may be from about 100 Å to about 10,000 Å, for example, from about 100 Å to about 1,000 Å.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole injection layer HIL may include, for example, a phthalocyanine compound such as copper phthalocyanine; N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino)triphenylamine (m-MTDATA), 4,4′,4″-tris(N,N-diphenylamino)triphenylamine (TDATA), 4,4′,4″-tris{N-(2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), 2,3,6,7,10,11-hexacyano-1,4,5,8,9,12-hexaazatriphenylene (HAT-CN), triphenylamine-containing polyether ketone (TPAPEK), 4-isopropyl-4′-methyldiphenyliodonium tetrakis(pentafluorophenyl)borate, etc.

The hole transport layer HTL may include, for example, a carbazole derivative such as N-phenyl carbazole, and polyvinyl carbazole, a fluorine derivative, N,N′-bis(3-methylphenyl)-N,N′-diphenyl-[1,1-biphenyl]-4,4′-diamine (TPD), a triphenylamine derivative such as 4,4′,4″-tris(N-carbazolyl)triphenylamine, N,N′-di(1-naphthyl)-N,N′-diphenylbenzidine (NPB), N,N′-diphenyl-N,N′-bis(1-naphthyl)-1,1′-biphenyl-4,4″-diamine (α-NPD), 4,4′-cyclohexylidene bis[N,N-bis(4-methylphenyl)benzenamine (TAPC), 4,4′-bis[N,N′-(3-tolyl)amino-3,3′-dimethylbiphenyl (HMTPD), etc.

The thickness of the hole transport region HTR may be from about 100 Å to about 10,000 Å, for example, from about 100 Å to about 1,000 Å. In the case where the hole transport region HTR includes both the hole injection layer HIL and the hole transport layer HTL, the thickness of the hole injection layer HIL may be from about 100 Å to about 10,000 Å, for example, from about 100 Å to about 1,000 Å, and the thickness of the hole transport layer HTL may be from about 30 Å to about 1,000 Å. In the case where the thicknesses of the hole transport region HTR, the hole injection layer HIL, and the hole transport layer HTL satisfy the above-described ranges, satisfactory hole transport properties may be obtained without a substantial increase of a driving voltage.

The hole transport region HTR may further include a charge generating material other than the above-described materials to improve conductivity. The charge generating material may be dispersed in the hole transport region HTR uniformly or non-uniformly. The charge generating material may be, for example, a p-dopant. The p-dopant may be one of a quinone derivative, a metal oxide, or a cyano group-containing compound, without limitation. For example, non-limiting examples of the p-dopant may include a quinone derivative such as tetracyanoquinodimethane (TCNQ), and 2,3,5,6-tetrafluoro-tetracyanoquinodimethane (F4-TCNQ), a metal oxide such as tungsten oxide, and molybdenum oxide, without limitation.

As described above, the hole transport region HTR may further include one of the hole buffer layer or the electron blocking layer in addition to the hole injection layer HIL and the hole transport layer HTL. In an implementation, the hole buffer layer may compensate an optical resonance distance according to the wavelength of light emitted from the emission layer EML and increase light emission efficiency. Materials included in the hole transport region may be used as materials included in the buffer layer. The electron blocking layer is a layer helping to prevent electron injection from the electron transport region ETR to the hole transport region HTR.

The emission layer EML is provided on the hole transport region HTR. The thickness of the emission layer EML may be, for example, from about 100 Å to about 300 Å. The emission layer EML may have a single layer formed using a single material, a single layer formed using a plurality of different materials, or a multilayer structure having a plurality of layers formed using a plurality of different materials.

The emission layer EML may emit, for example, one of red light, green light, blue light, white light, yellow light, or cyan light. The emission layer EML may include a first compound represented by the following Formula 1 and a second compound represented by the following Formula 2. The first compound may be a dopant, and the second compound may be a host. The host may be present in a greater weight percentage than the dopant. The triplet excitation energy of the second compound may be higher than the singlet excitation energy of the first compound.

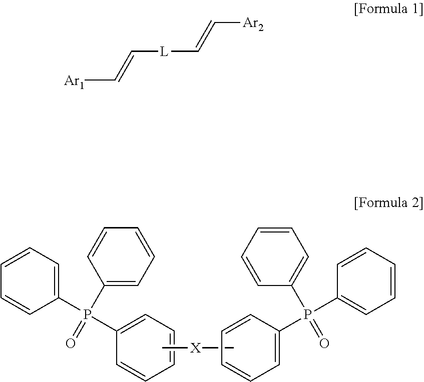

In Formula 1, L may be selected from a substituted or unsubstituted arylene having 6 to 30 carbon atoms for forming a ring, or a substituted or unsubstituted heteroarylene having 4 to 30 carbon atoms for forming a ring.

L may be selected from, for example, the following A-1 to A-6.

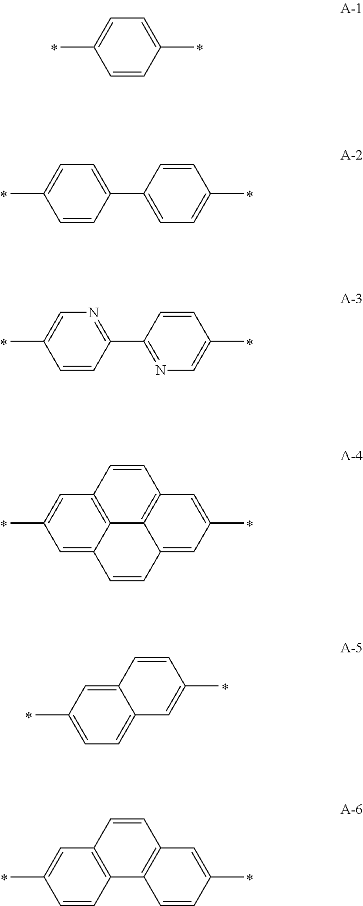

In A-1 to A-6, * represents a binding site.

In Formula 2, X is a divalent linker. X may be O.

In Formula 1, Ar₁ and Ar₂ may each be independently represented by the following Formula 3.

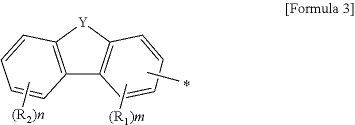

In Formula 3, * represents a binding site.

In an example embodiment, Ar₁ and Ar₂ may be each independently selected from a substituted or unsubstituted carbazole, a substituted or unsubstituted dibenzofuran, a substituted or unsubstituted dibenzothiophene, a substituted or unsubstituted fluorenyl, or a substituted or unsubstituted dibenzosilole.

Ar₁ and Ar₂ may be the same, however an embodiment is not limited thereto, and Ar₁ and Ar₂ may be different from each other.

In Formula 3, R₁ and R₂ may each independently be selected from a substituted or unsubstituted alkyl having 1 to 20 carbon atoms, a substituted or unsubstituted aryl having 6 to 30 carbon atoms for forming a ring, a substituted or unsubstituted heteroaryl having 4 to 30 carbon atoms for forming a ring, a substituted or unsubstituted alkoxy, a substituted or unsubstituted aryloxy, a substituted or unsubstituted amino, a substituted or unsubstituted cyano, a substituted or unsubstituted silyl, a halogen, deuterium, or hydrogen.

R₁ and R₂ may each independently be selected from, for example, the following B-1 to B-8.

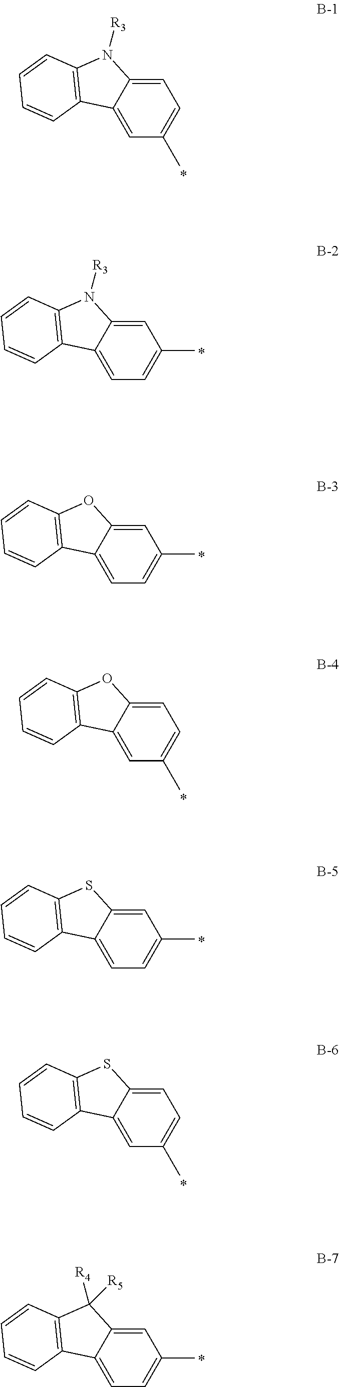

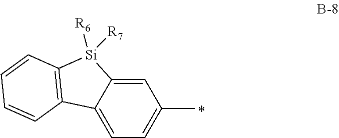

In Formulae B-1 to B-8, * represents a binding site.

In Formula 3, Y may be selected from, for example, O, S, NR₃, CR₄R₅, or SiR₆R₇.

In Formula 3, R₃, R₄, R₅, R₆, and R₇ may each independently be selected from a substituted or unsubstituted alkyl having 1 to 20 carbon atoms, a substituted or unsubstituted aryl having 6 to 30 carbon atoms for forming a ring, or a substituted or unsubstituted heteroaryl having 4 to 30 carbon atoms for forming a ring. In Formula 3, m may be an integer of 0 to 3, and n may be an integer of 0 to 4.

In Formula 3, R₃ may be, for example, ethyl or phenyl. In Formula 3, R₄ and R₅ may each independently be, for example, methyl or phenyl. In Formula 3, R₆ and R₇ may each independently be, for example, methyl or phenyl.

The first compound may include, for example, at least one of the compounds represented in the following Compound Group 1.

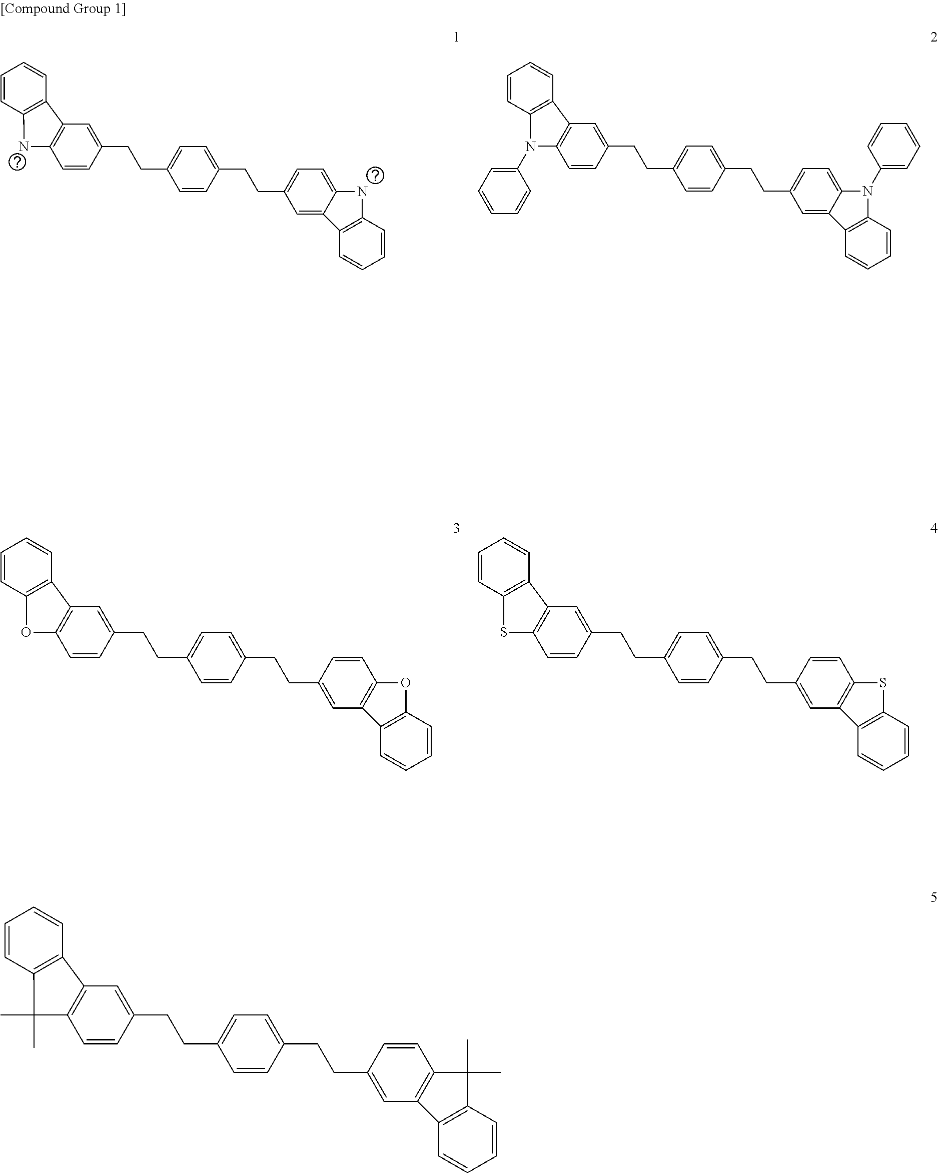

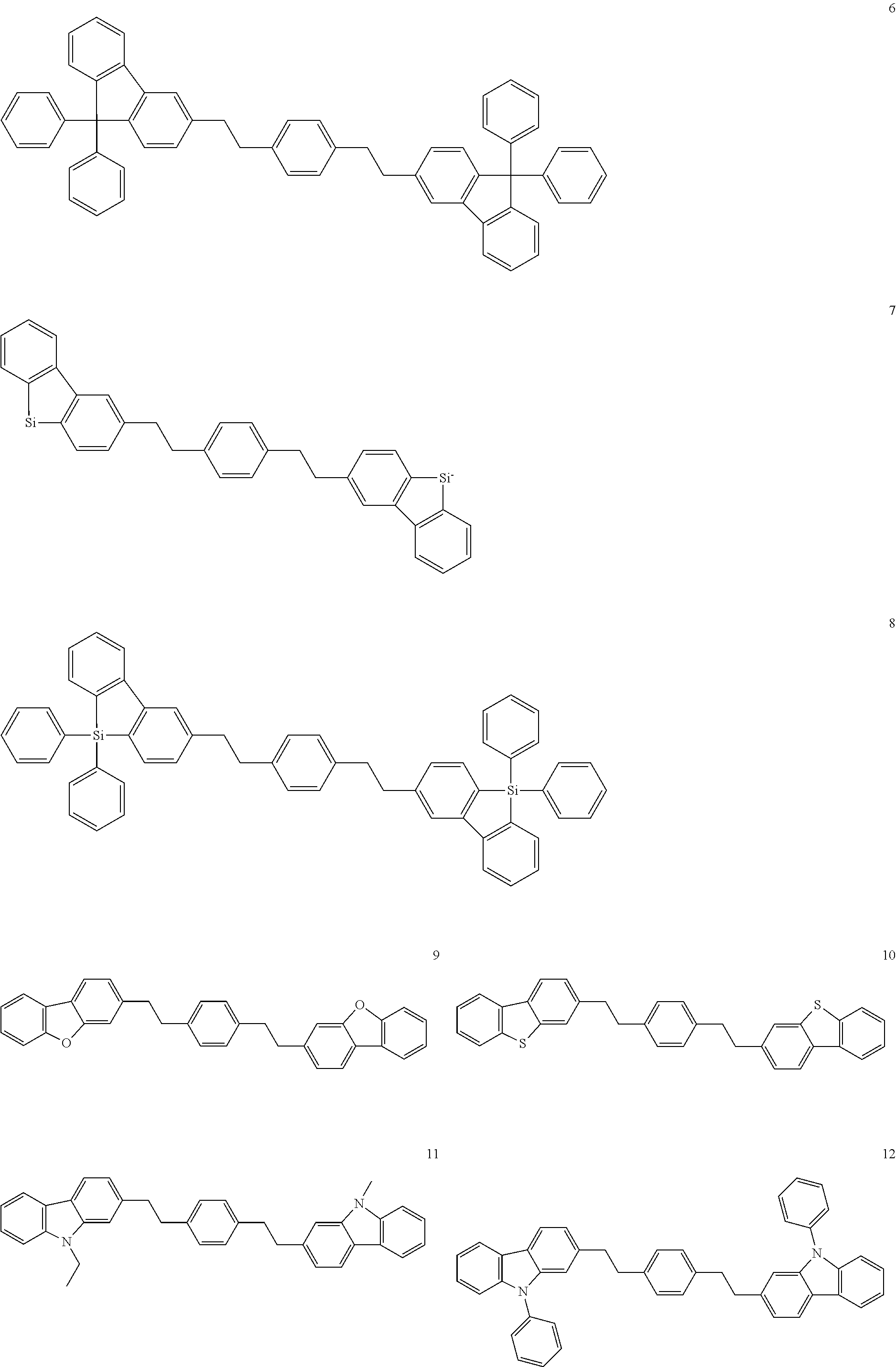

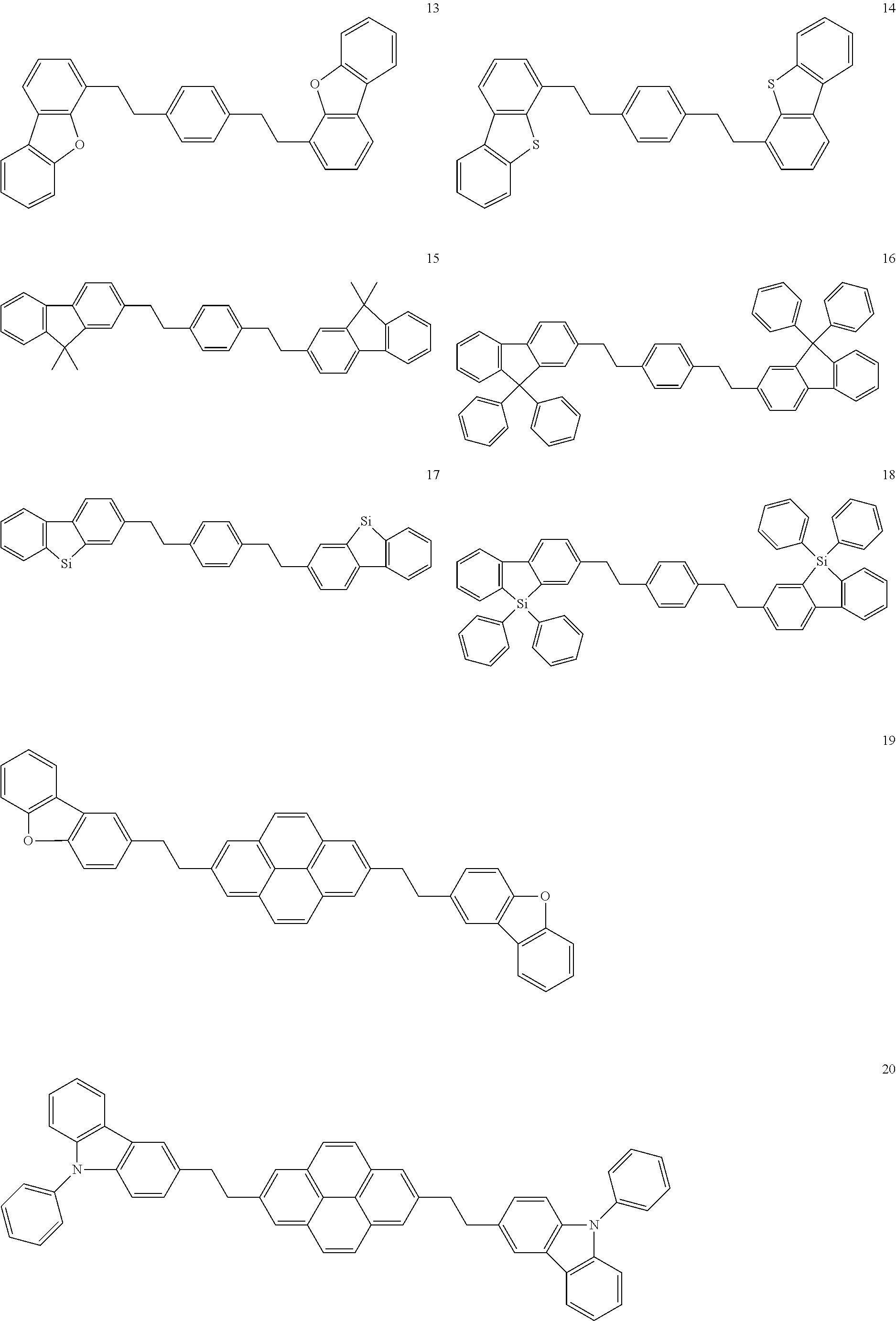

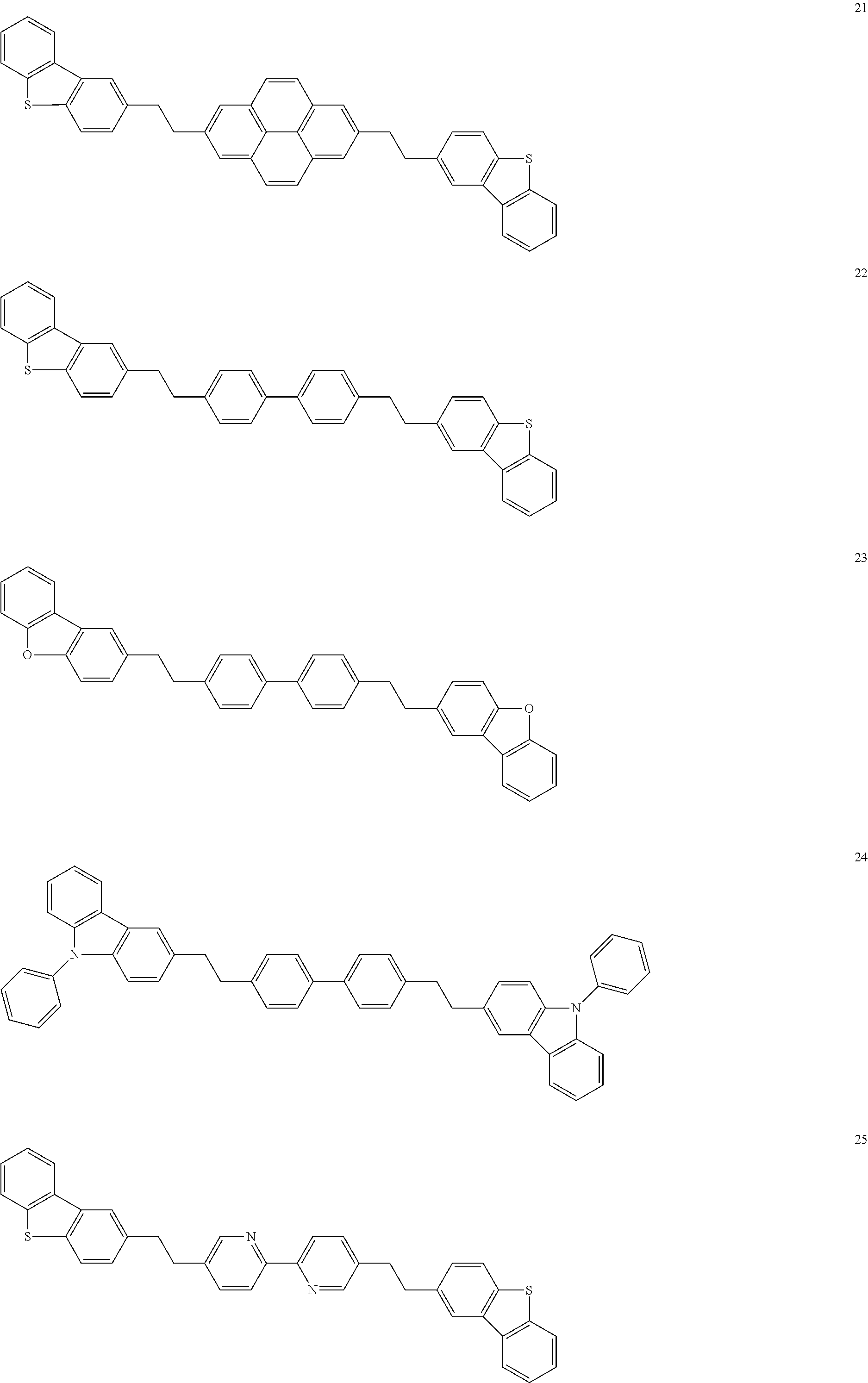 [SMILES: c1ccc2c(c1)sc1ccc(CCc3cc4ccc5cc(CCc6ccc7sc8ccccc8c7c6)cc6ccc(c3)c4c56)cc12 ; c1ccc2c(c1)sc1ccc(CCc3ccc(-c4ccc(CCc5ccc6sc7ccccc7c6c5)cc4)cc3)cc12 ; c1ccc2c(c1)oc1ccc(CCc3ccc(-c4ccc(CCc5ccc6oc7ccccc7c6c5)cc4)cc3)cc12 ; c1ccc(-n2c3ccccc3c3cc(CCc4ccc(-c5ccc(CCc6ccc7c(c6)c6ccccc6n7-c6ccccc6)cc5)cc4)ccc32)cc1 ; c1ccc2c(c1)sc1ccc(CCc3ccc(-c4ccc(CCc5ccc6sc7ccccc7c6c5)cn4)nc3)cc12]

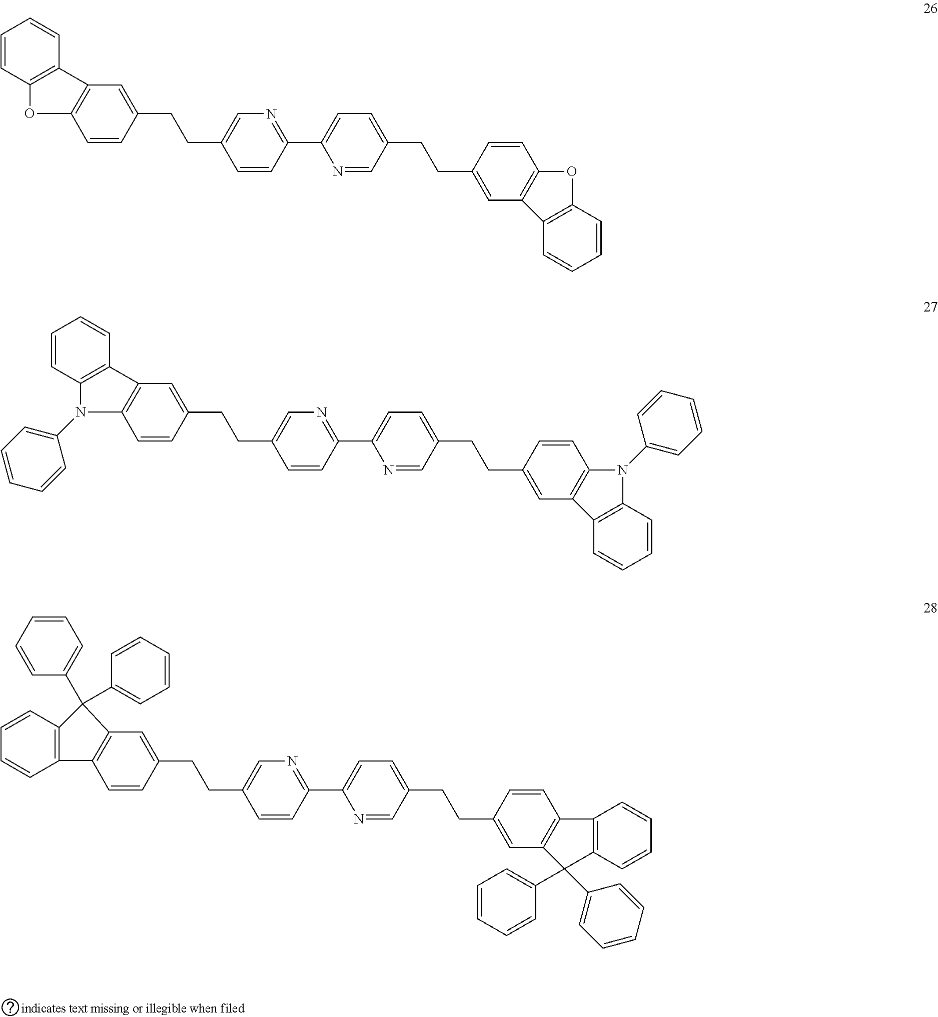 [SMILES: c1ccc2c(c1)oc1ccc(CCc3ccc(-c4ccc(CCc5ccc6oc7ccccc7c6c5)cn4)nc3)cc12 ; c1ccc(-n2c3ccccc3c3cc(CCc4ccc(-c5ccc(CCc6ccc7c(c6)c6ccccc6n7-c6ccccc6)cn5)nc4)ccc32)cc1 ; c1ccc(C2(c3ccccc3)c3ccccc3-c3ccc(CCc4ccc(-c5ccc(CCc6ccc7c(c6)C(c6ccccc6)(c6ccccc6)c6ccccc6-7)cn5)nc4)cc32)cc1]

The second compound may include, for example, at least one compound represented in the following Compound Group 2.

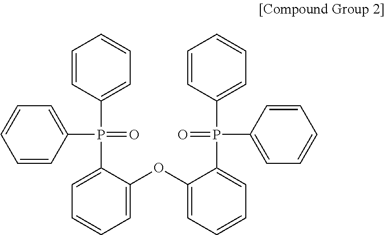 [SMILES: O=P(c1ccccc1)(c1ccccc1)c1ccccc1Oc1ccccc1P(=O)(c1ccccc1)c1ccccc1]

The electron transport region ETR may be provided on the emission layer EML. The electron transport region ETR may include at least one of an electron blocking layer, an electron transport layer ETL, and an electron injection layer EIL, without limitation.

The electron transport region ETR may have, for example, a single layer formed using a single material, a single layer formed using a plurality of different materials, or a multilayer structure including a plurality of layers formed using a plurality of different materials.

For example, the electron transport region ETR may have the structure of a single layer such as the electron injection layer EIL or the electron transport layer ETL, a single layer structure formed using an electron injection material and an electron transport material. In addition, the electron transport region ETR may have a single layer structure formed using a plurality of different materials, or a structure laminated from the anode AN of electron transport layer ETL/electron injection layer EIL, or hole blocking layer/electron transport layer ETL/electron injection layer EIL, without limitation. The thickness of the electron transport region ETR may be, for example, from about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

When the electron transport region ETR includes the electron transport layer ETL, the electron transport region ETR may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen). 3-(4-biphenylyl)-4-phenyl-5-tert-butylphenyl-1,2,4-triazole (TAZ). 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq2), 9,10-di(naphthalene-2-yl)anthracene (ADN), or a mixture thereof, without limitation. The thickness of the electron transport layer ETL may be, for example, from about 100 Å to about 1,000 Å and may be from about 150 Å to about 500 Å. If the thickness of the electron transport layer ETL satisfies the above-described range, satisfactory electron transport properties may be obtained without a substantial increase of a driving voltage.

In the case where the electron transport region ETR includes the electron injection layer EIL, the electron transport region ETR may include, for example, LiF, lithium quinolate (LiQ), Li₂O, BaO, NaCl, CsF, a metal in lanthanides such as Yb, or a metal halide such as RbCl and RbI, without limitation. The electron injection layer EIL also may be formed, for example, using a mixture material of a hole transport material and an insulating organo metal salt. The organo metal salt may be, for example, a material having an energy band gap of about 4 eV or more. In an implementation, the organo metal salt may include, for example, a metal acetate, a metal benzoate, a metal acetoacetate, a metal acetylacetonate, or a metal stearate. The thickness of the electron injection layer EIL may be, for example, from about 1 Å to about 100 Å, and from about 3 Å to about 90 Å. In the case where the thickness of the electron injection layer EIL satisfies the above described range, satisfactory electron injection property may be obtained without inducing a substantial increase of a driving voltage.

The electron transport region ETR may include a hole blocking layer, as described above. The hole blocking layer may include at least one of, for example, 2,9-dimethyl-4,7-diphenyl-1,10-phenanthroline (BCP), or 4,7-diphenyl-1,10-phenanthroline (Bphen), without limitation.

The cathode CAT may be provided on the electron transport region ETR. The cathode CAT may be a common electrode or cathode. The cathode CAT may be, for example, a transmissive electrode, a transflective electrode, or a reflective electrode. In the case where the cathode CAT is the transmissive electrode, the cathode CAT may include, for example, a transparent metal oxide, for example, ITO, IZO, ZnO, ITZO, etc.

In the case where the cathode CAT is the transflective electrode or the reflective electrode, the cathode CAT may include, for example, Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The cathode CAT may have, for example, a multilayered structure including a reflective layer or a transflective layer formed using the above-described materials and a transparent conductive layer formed using ITO, IZO, ZnO, ITZO, etc.

The cathode CAT may be connected with an auxiliary electrode. If the cathode CAT is connected with the auxiliary electrode, the resistance of the cathode CAT may decrease.

In the organic electroluminescence device 10, voltages are applied to each of the anode AN and the cathode CAT, and holes injected from the anode AN move via the hole transport region HTR to the emission layer EML, and electrons injected from the cathode CAT move via the electron transport region ETR to the emission layer EML. The electrons and the holes are recombined in the emission layer EML to generate excitons, and light may be emitted via the transition of the excitons from an excited state to a ground state.

In the case where the organic electroluminescence device 10 is a top emission type, the anode AN may be a reflective electrode, and the cathode CAT may be a transmissive electrode or a transflective electrode. In the case where the organic electroluminescence device 10 is a bottom emission type, the anode AN may be a transmissive electrode or a transflective electrode, and the cathode CAT may be a reflective electrode.

The organic electroluminescence device according to an example embodiment includes the first compound represented by Formula 1. The triplet excitation energy of the second compound may be higher than the singlet excitation energy of the first compound, and emission efficiency of the device may be improved.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLES

[Manufacture of Organic Electroluminescence Device]

An anode was formed using ITO to a thickness of about 150 nm, a hole injection layer was formed using HAT-CN to a thickness of about 10 nm, a hole transport layer was formed using α-NPD to a thickness of about 80 nm, an electron blocking layer was formed using mCP to a thickness of about 5 nm, an emission layer was formed by doping a host with 6 wt % of a dopant to a thickness of about 20 nm, an electron transport layer was formed using TPBi to a thickness of about 30 nm, an electron injection layer was formed using LiF to a thickness of about 105 nm, and an anode was formed using Al to a thickness of about 100 nm.

Each of the host and the dopant used in Example 1, and Comparative Examples 1 to 3 are indicated in Tables 1 and 2 below.

In addition, the triplet energy of the host was measured via phosphorescence emission spectrum at a low temperature, e.g., a temperature less than room temperature, and the singlet energy of the dopant was measured via fluorescence emission spectrum at room temperature. The results are shown in Table 3 below.

The current density of a device was measured using a Source meter of 2400 Series manufactured by Keithley Instruments, the voltage was measured using a luminance colorimeter CS-200 manufactured by Konica Minolta Holdings, and the quantum efficiency was measured using a brightness light distribution characteristics measurement system C9920-11 manufactured by Hamamatsu Photonics Co.

TABLE 1

| Device | | | Initiation | External |
|---|---|---|---|---|
| manufacturing | | | voltage (V, 10 | quantum |
| example | Host | Dopant | mA/cm²) | efficiency (%) |
| Example 1 | DPEPO | Compound 1 | 8 | 7 |
| Comparative | ADN | Compound 1 | 4 | 3 |
| Example 1 | | | | |
| Comparative | DPEPO | TBPe | 9 | 0.4 |
| Example 2 | | | | |
| Comparative | ADN | TBPe | 4 | 1 |
| Example 3 | | | | |

TABLE 2

| Compound | Formula |
|---|---|
| HAT-CN | 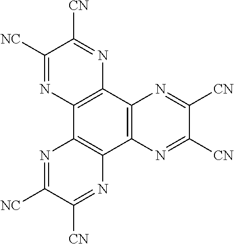 [SMILES: N#Cc1nc2c3nc(C#N)c(C#N)nc3c3nc(C#N)c(C#N)nc3c2nc1C#N] |
| α-NPD | 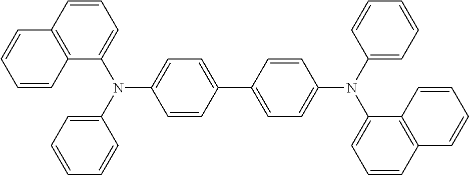 [SMILES: c1ccc(N(c2ccc(-c3ccc(N(c4ccccc4)c4cccc5ccccc45)cc3)cc2)c2cccc3ccccc23)cc1] |
| mCP | 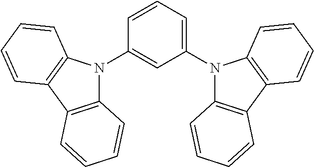 [SMILES: c1cc(-n2c3ccccc3c3ccccc32)cc(-n2c3ccccc3c3ccccc32)c1] |
| DPEPO | 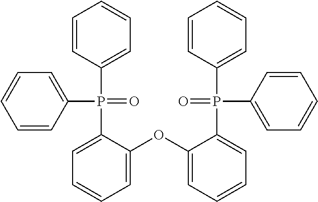 [SMILES: O=P(c1ccccc1)(c1ccccc1)c1ccccc1Oc1ccccc1P(=O)(c1ccccc1)c1ccccc1] |
| TPBi | 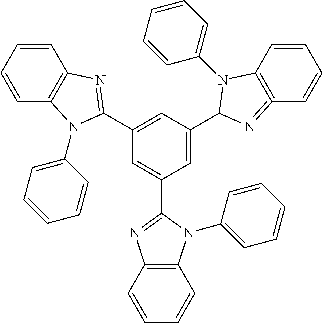 |
| ADN | 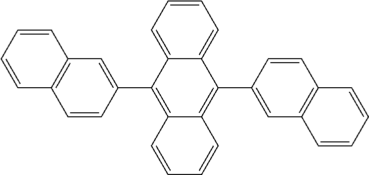 [SMILES: c1ccc2cc(-c3c4ccccc4c(-c4ccc5ccccc5c4)c4ccccc34)ccc2c1] |
| TBPe | 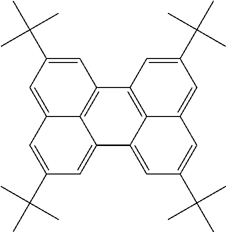 [SMILES: CC(C)(C)c1cc2cc(C(C)(C)C)cc3c4cc(C(C)(C)C)cc5cc(C(C)(C)C)cc(c(c1)c23)c54] |
| Compound 1 | 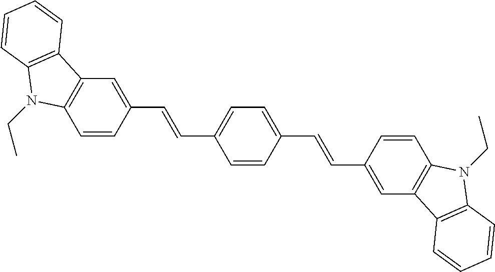 [SMILES: CCn1c2ccccc2c2cc(/C=C/c3ccc(/C=C/c4ccc5c(c4)c4ccccc4n5CC)cc3)ccc21] |

TABLE 3

| Compound | Triplet energy | Singlet energy |
|---|---|---|
| DPEPO | 3.6 eV | — |
| ADN | 2.6 eV | — |
| Compound 1 | — | 3.1 eV |
| TBPe | — | 2.83 eV |

Referring to Table 1, it can be seen that the external quantum efficiency of the organic electroluminescence device of Example 1 was higher than the organic electroluminescence devices Comparative Examples 1 to 3.

By way of summation and review, as an organic electroluminescence device, an organic device including, for example, an anode, a hole transport layer disposed on the anode, an emission layer disposed on the hole transport layer, an electron transport region disposed on the emission layer, and a cathode disposed on the electron transport region may be fabricated. Holes are injected from the anode, and the injected holes move and are injected to the emission layer. Meanwhile, electrons are injected from the cathode, and the injected electrons move and are injected to the emission layer. The holes and the electrons injected to the emission layer recombine to produce excitons in the emission layer. The organic electroluminescence device may emit light via the radiation deactivation of the excitons. The configuration of the organic electroluminescence device is not limited to the above-described configuration, and various modifications may be possible. For the application of the organic electroluminescence device to a display, the decrease of a driving voltage, and the increase of emission efficiency and life thereof are desirable.

As described above, an organic electroluminescence device according to an example embodiment may achieve high emission efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic electroluminescence device, comprising:
an anode;
a hole transport region provided on the anode;
an emission layer provided on the hole transport region;
an electron transport region provided on the emission layer; and
a cathode provided on the electron transport region,
wherein the emission layer includes a first compound represented by the following Formula 1 and a second compound represented by the following Formula 2: 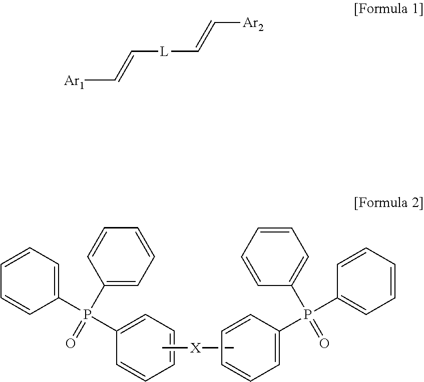
where L is selected from a substituted or unsubstituted arylene having 6 to 30 carbon atoms for forming a ring, or a substituted or unsubstituted heteroarylene having 4 to 30 carbon atoms for forming a ring,
X is a divalent linker, and
Ar₁ and Ar₂ are each independently represented by the following Formula 3: 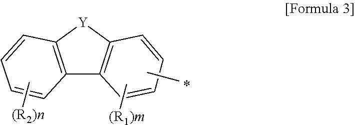
wherein Y is selected from O, S, NR₃, CR₄R₅, or SiR₆R₇,
R₁ and R₂ are each independently selected from a substituted or unsubstituted alkyl having 1 to 20 carbon atoms, a substituted or unsubstituted aryl having 6 to 30 carbon atoms for forming a ring, a substituted or unsubstituted heteroaryl having 4 to 30 carbon atoms for forming a ring, a substituted or unsubstituted alkoxy, a substituted or unsubstituted aryloxy, a substituted or unsubstituted amino, a substituted or unsubstituted cyano, a substituted or unsubstituted silyl, a halogen, deuterium, or hydrogen,
R₃, R₄, R₅, R₆, and R₇ are each independently selected from a substituted or unsubstituted alkyl having 1 to 20 carbon atoms, a substituted or unsubstituted aryl having 6 to 30 carbon atoms for forming a ring, or a substituted or unsubstituted heteroaryl having 4 to 30 carbon atoms for forming a ring,
m is an integer of 0 to 3, and
n is an integer of 0 to 4.

2. The organic electroluminescence device as claimed in claim 1, wherein a triplet excitation energy of the second compound is higher than a singlet excitation energy of the first compound.

3. The organic electroluminescence device as claimed in claim 1, wherein Ar₁ and Ar₂ in Formula 1 are the same.

4. The organic electroluminescence device as claimed in claim 1, wherein Ar₁ and Ar₂ in Formula 1 are each independently selected from a substituted or unsubstituted carbazole, a substituted or unsubstituted dibenzofuran, a substituted or unsubstituted dibenzothiophene, a substituted or unsubstituted fluorenyl, or a substituted or unsubstituted dibenzosilole.

5. The organic electroluminescence device as claimed in claim 1, wherein L in Formula 1 is selected from the following A-1 to A-6:

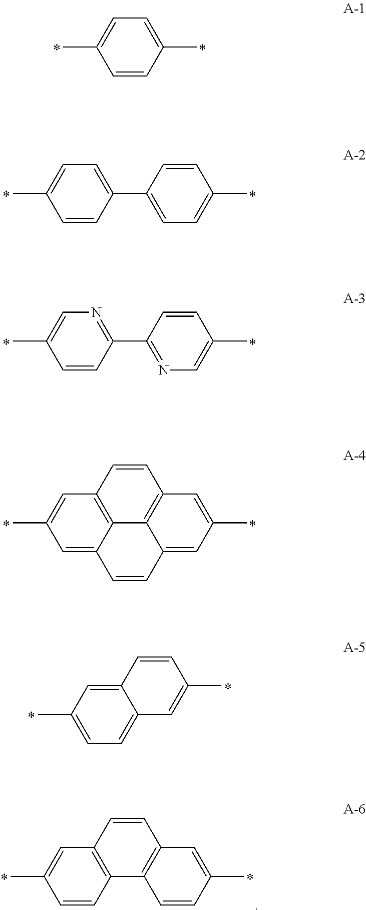

6. The organic electroluminescence device as claimed in claim 1, wherein X in Formula 2 is O.

7. The organic electroluminescence device as claimed in claim 1, wherein Ar₁ and Ar₂ are each independently selected from the following B-1 to B-8: 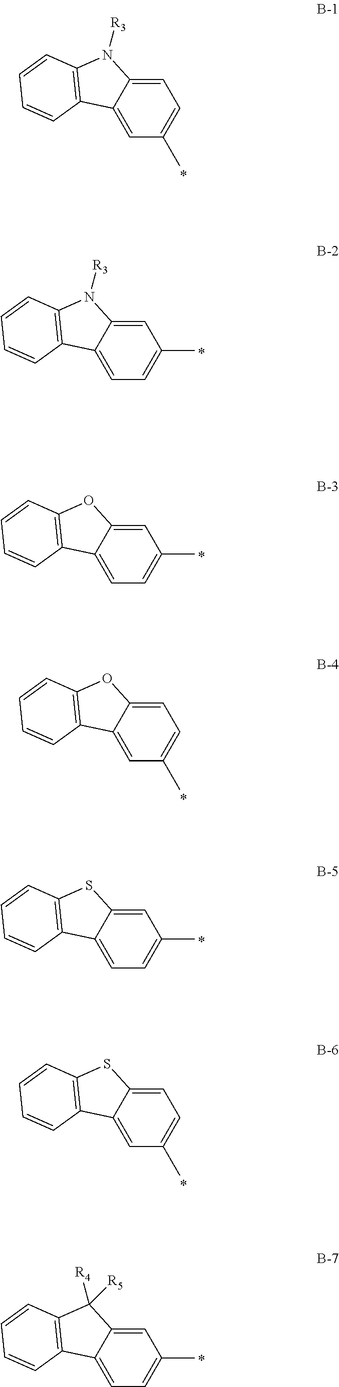 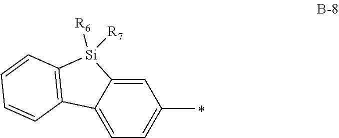
where R₃, R₄, R₅, R₆, and R₇ are defined the same as in claim 1.

8. The organic electroluminescence device as claimed in claim 1, wherein Y is NR₃, and R₃ in Formula 3 is ethyl or phenyl.

9. The organic electroluminescence device as claimed in claim 1, wherein Y is CR₄R₅, and R₄ and R₅ in Formula 3 are each independently methyl or phenyl.

10. The organic electroluminescence device as claimed in claim 1, wherein Y is SiR₆R₇, and R₆ and R₇ in Formula 3 are each independently methyl or phenyl.

11. The organic electroluminescence device as claimed in claim 1, wherein the first compound includes at least one of the compounds represented in the following Compound Group 1:

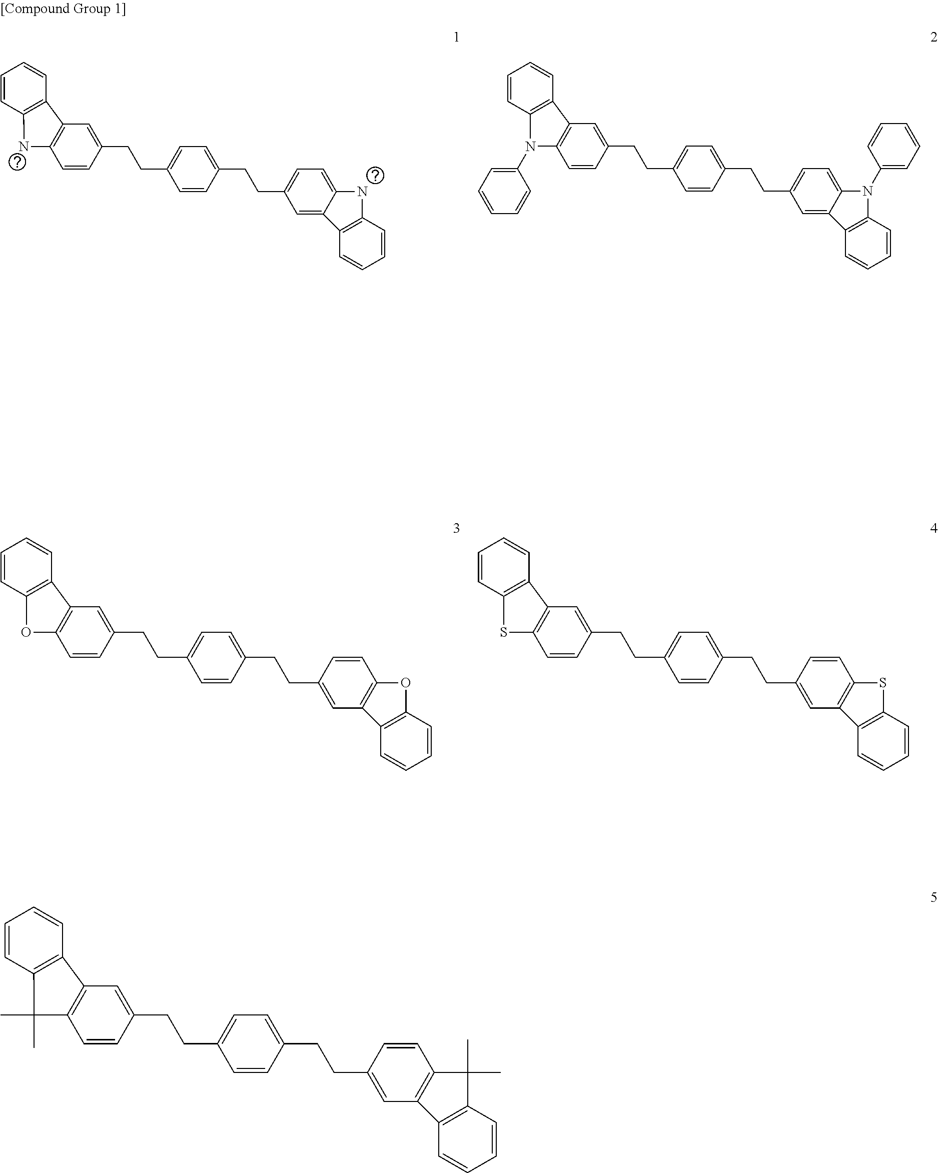

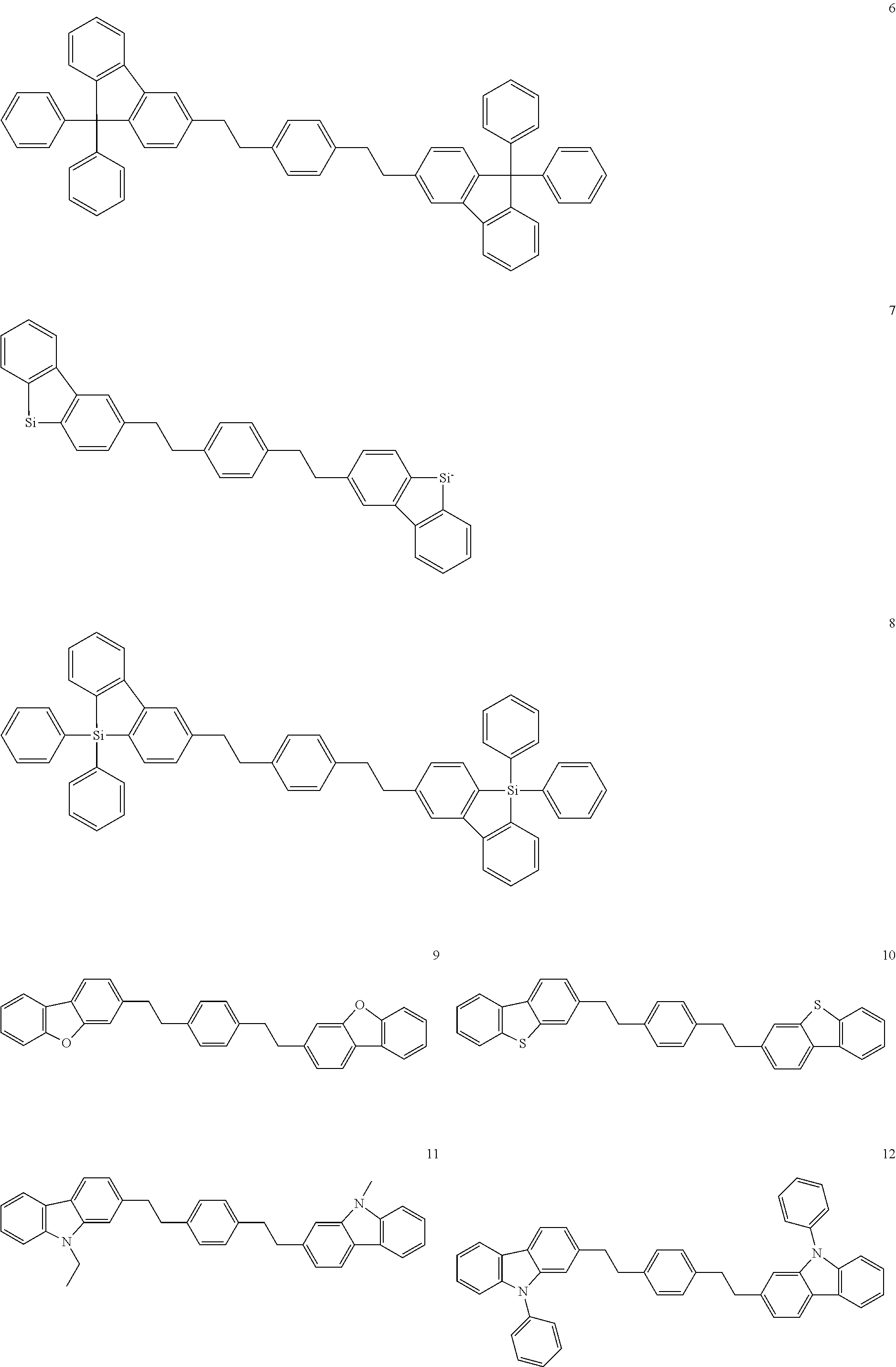

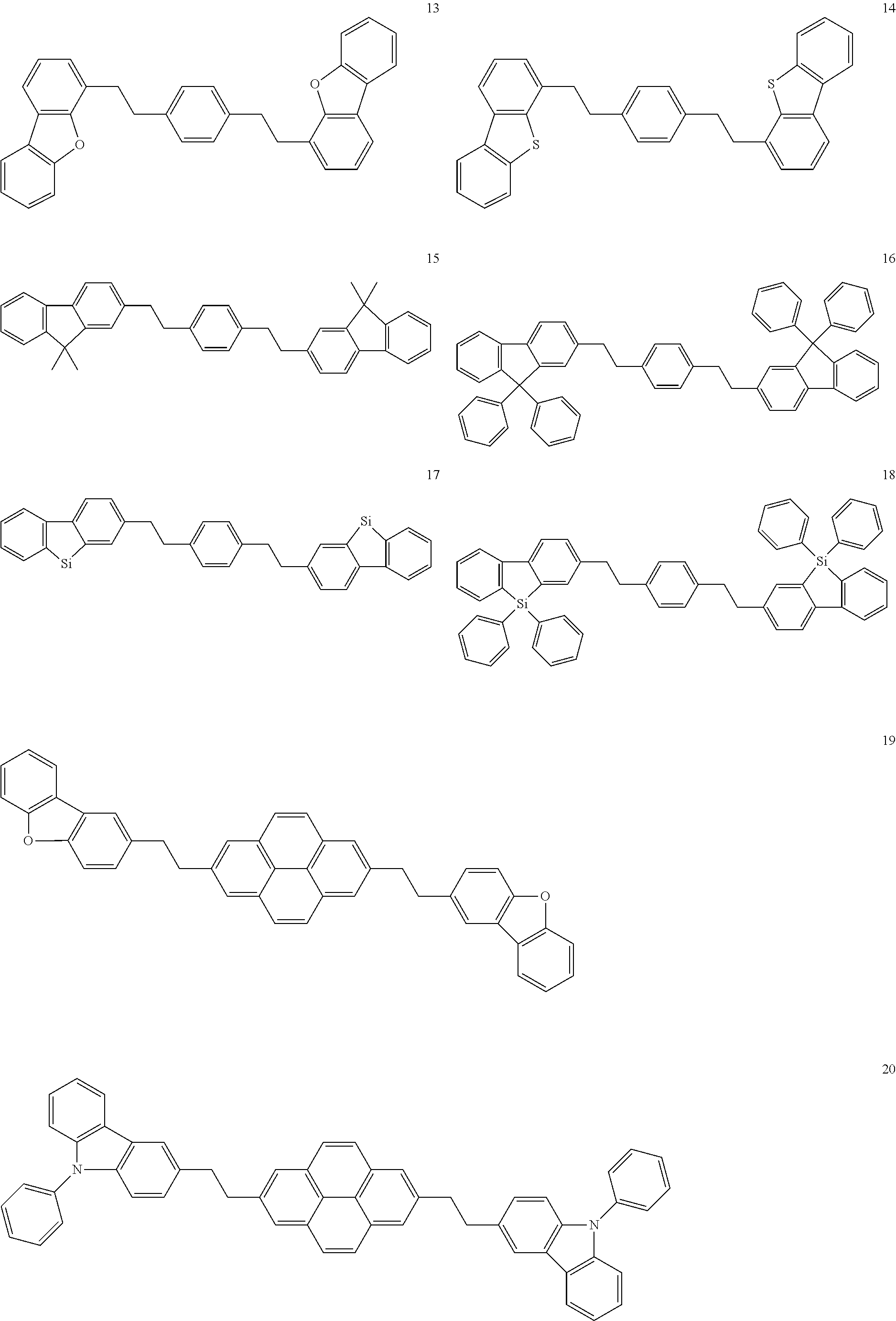

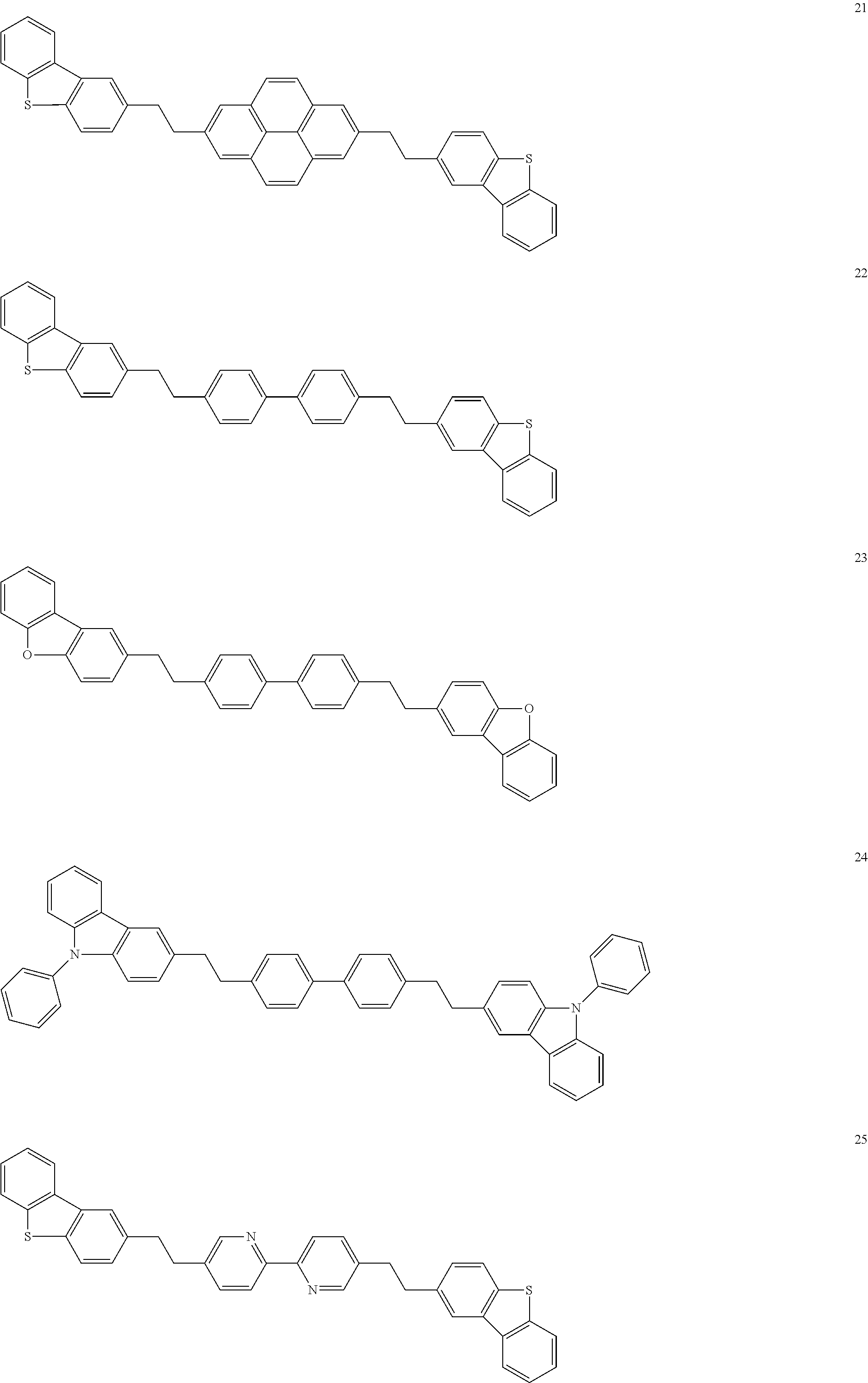 [SMILES: c1ccc2c(c1)sc1ccc(CCc3cc4ccc5cc(CCc6ccc7sc8ccccc8c7c6)cc6ccc(c3)c4c56)cc12 ; c1ccc2c(c1)sc1ccc(CCc3ccc(-c4ccc(CCc5ccc6sc7ccccc7c6c5)cc4)cc3)cc12 ; c1ccc2c(c1)oc1ccc(CCc3ccc(-c4ccc(CCc5ccc6oc7ccccc7c6c5)cc4)cc3)cc12 ; c1ccc(-n2c3ccccc3c3cc(CCc4ccc(-c5ccc(CCc6ccc7c(c6)c6ccccc6n7-c6ccccc6)cc5)cc4)ccc32)cc1 ; c1ccc2c(c1)sc1ccc(CCc3ccc(-c4ccc(CCc5ccc6sc7ccccc7c6c5)cn4)nc3)cc12]

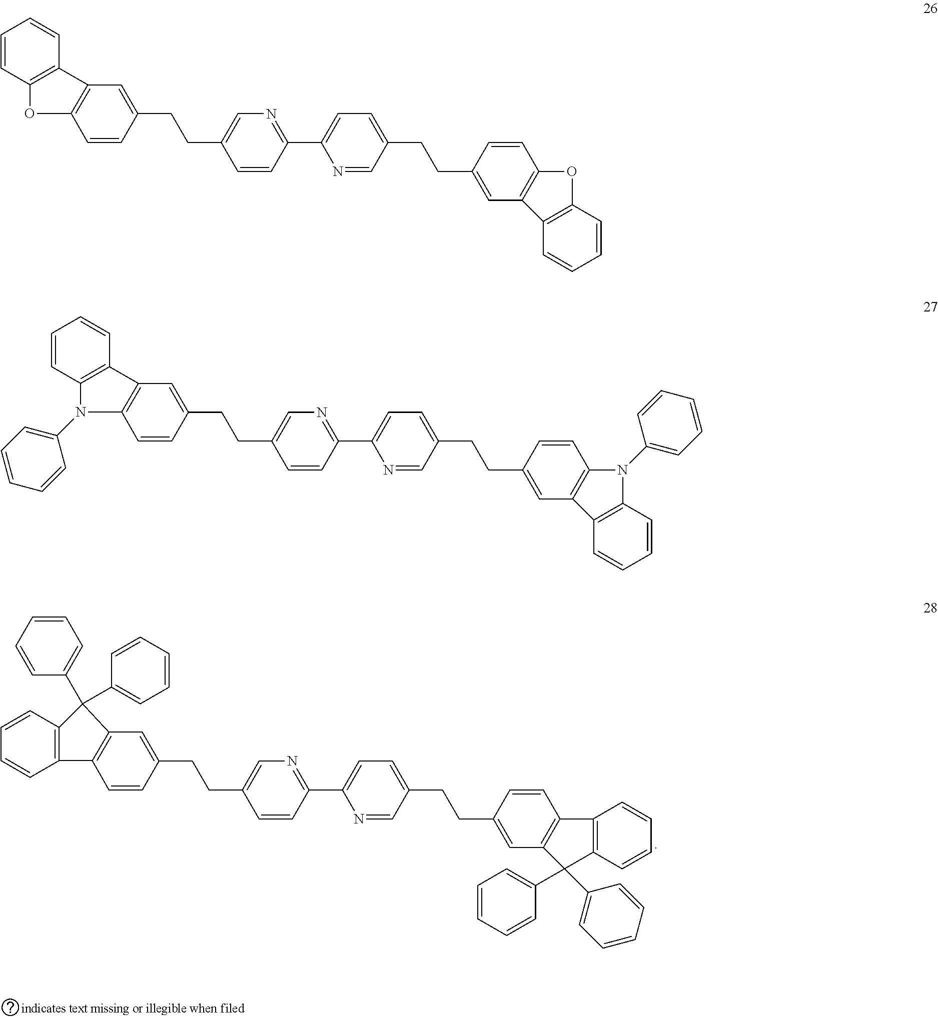 [SMILES: c1ccc2c(c1)oc1ccc(CCc3ccc(-c4ccc(CCc5ccc6oc7ccccc7c6c5)cn4)nc3)cc12 ; c1ccc(-n2c3ccccc3c3cc(CCc4ccc(-c5ccc(CCc6ccc7c(c6)c6ccccc6n7-c6ccccc6)cn5)nc4)ccc32)cc1 ; c1ccc(C2(c3ccccc3)c3ccccc3-c3ccc(CCc4ccc(-c5ccc(CCc6ccc7c(c6)C(c6ccccc6)(c6ccccc6)c6ccccc6-7)cn5)nc4)cc32)cc1]

12. The organic electroluminescence device as claimed in claim 1, wherein the second compound is

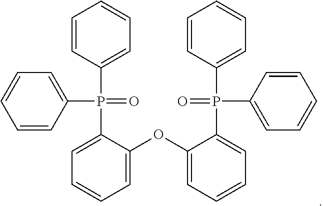 [SMILES: O=P(c1ccccc1)(c1ccccc1)c1ccccc1Oc1ccccc1P(=O)(c1ccccc1)c1ccccc1]

13. The organic electroluminescence device as claimed in claim 1, wherein the first compound is a dopant, and the second compound is a host, the host being present in a greater weight percentage than the dopant in the emission layer.

14. The organic electroluminescence device as claimed in claim 1, wherein the hole transport region includes:
a hole injection layer; and
a hole transport layer provided on the hole injection layer.

15. The organic electroluminescence device as claimed in claim 1, wherein the electron transport region includes:
an electron transport layer; and
an electron injection layer provided on the electron transport layer.
